(19) United States
(12) Patent Application Publication
(10) Pub. No.: US 2012/0246537 A1
(43) Pub. Date: Sep. 27, 2012

(54) ERROR CORRECTION METHOD AND DEVICE

(75) Inventors: Kazuo Kubo, Tokyo (JP); Takashi Mizuochi, Tokyo (JP)

(73) Assignee: MITSUBISHI ELECTRIC CORPORATION, Tokyo (JP)

(21) Appl. No.: 13/513,411

(22) PCT Filed: Nov. 19, 2010
(86) PCT No.: PCT/JP2010/070703

§ 371 Date: Jun. 1, 2012

(30) Foreign Application Priority Data
Dec. 1, 2009 (JP) 2009-273204

(51) Int. Cl. H03M 13/05; G06F 11/10

(52) U.S. Cl. 714/752; 714/E11.032

(57) ABSTRACT

Provided is an error correction method for an optical communication system that transmits a transmission frame formed of information data added with an overhead and an error correction code, the error correction method including adjusting a size of an FEC redundant area of an FEC frame for storing client signals of different signal types in accordance with the client signals so that transmission rates of the FEC frame for the respective client signals have an approximately N-multiple relationship (N is a positive natural number). With this, it is possible to obtain an error correction method and device capable of providing a high-quality and high-speed optical communication system without performance degradation caused by jitter or the like and with the common use of circuits having a reduced circuit scale.

### TECHNICAL FIELD

The present invention relates to an error correction method and device applicable to a digital communication device such as an optical communication system.

### BACKGROUND ART

A conventional error correction method and device apply a Reed-Solomon code RS (255,239) as a forward error correction (FEC) coding scheme (see, for example, Non Patent Literature 1). Another error correction method that uses a low-density parity-check (LDPC) code as an inner code and an RS code as an outer code has been proposed (see, for example, Patent Literature 1).

The error correction device using the error correction coding scheme disclosed in Non Patent Literature 1 and Patent Literature 1 above is based on the frame configuration having the same information area and the same redundant area irrespective of the transmission rate. For example, the transmission rate for a 10 Gb/s client signal is 10.7 Gb/s using an optical channel transport unit-2 (OTU2) frame, and the transmission rate for a 40 Gb/s client signal is 43.0 Gb/s using an optical channel transport unit-3 (OTU3) frame.

### CITATION LIST

### Patent Literature

[PTL 1] JP 2009-17160 A

### Non Patent Literature

[NPL 1] ITU-T Recommendation G.709/Y.1331 Interface for the Optical Transport Network (OTN), Annex A, ITU-T Rec. G.709/Y.1331 (March/2003)

### SUMMARY OF INVENTION

### Technical Problems

The configuration of the conventional error correction method and device is based on the frame configuration having the same information area and the same redundant area. Regarding the transmission rate of an OTUk frame for client signals of different signal types, for example, the OTU4 frame for a 100 Gb/s client signal has a transmission rate of 111.8 Gb/s, which is about 2.6 times a transmission rate of 43.0 Gb/s of the OTU3 frame for a 40 Gb/s client signal. Therefore, for the common use of components of the error correction device, such as an analog/digital converter, a digital/analog converter, and a serializer/de-serializer (SerDes), between processing of both OTU4 and OTU3, it is required to operate a clock generation circuit necessary for those functions, such as a clock multiplier unit (CMU), a phase lock to loop (PLL), or a clock-data recovery (CDR), at two kinds of significantly different frequencies. Widening the operating frequency range of the CMU, the CDR, or the PLL thus causes a problem of clock quality degradation such as jitter and transmission performance degradation. The clock quality degradation can be prevented by providing two voltage-controlled oscillators (VCOs) and switching the use of the VCO in accordance with the transmission rate. There has been, however, a problem of an increased circuit scale.

The present invention has been made in order to solve the above-mentioned problems, and it is an object thereof to provide an error correction method and device, which can provide a high-quality and high-speed optical communication system without performance degradation caused by jitter or the like and with the common use of circuits having a reduced circuit scale.

### Solution to Problems

According to the present invention, there is provided an error correction method for an optical communication system that transmits a transmission frame formed of information data added with an overhead and an error correction code, the error correction method including adjusting a size of an FEC redundant area of an FEC frame for storing client signals of different signal types in accordance with the client signals so that transmission rates of the FEC frame for the respective client signals have an approximately N-multiple relationship (N is a positive natural number).

Further, according to the present invention, there is provided an error correction device for an optical communication system that transmits a transmission frame formed of information data added with an overhead and an error correction code, the error correction device including: an optical transmission framer for generating an optical transmission frame based on mapping of a client transmission signal into an optical channel transmission frame and outputting a transmission signal, and for demapping a client signal from the optical channel transmission frame based on an input of a reception signal and outputting a client reception signal; an FEC encoder for encoding the transmission signal sent from the optical transmission framer by the error correction code; a D/A converter for performing D/A conversion on an output signal of the FEC encoder and outputting an optical transmission signal to a communication path; an A/D converter for converting an optical reception signal sent from the communication path into an analog signal; and an FEC decoder for decoding reception data from an output of the A/D converter to correct an error, and outputting the reception signal to the optical transmission framer, in which each of the D/A converter and the A/D converter includes clock generation means for changing a sampling clock in accordance with client signals of different signal types, and the error correction device adjusts a size of an FEC redundant area of an FEC frame for storing the client signals of different signal types in accordance with the client signals so that transmission rates of the FEC frame for the respective client signals have an approximately N-multiple relationship (N is a positive natural number).

### Advantageous Effects of Invention

According to the present invention, in the FEC frame for storing the client signals of different signal types, the size of the FEC redundant area is adjusted in accordance with the client signals so that the transmission rates of the FEC frame for the respective client signals have an approximately N-multiple relationship (N is a positive natural number). It is therefore possible to provide a high-quality and high-speed optical communication system without performance degradation caused by jitter or the like and with the common use of circuits having a reduced circuit scale.

### BRIEF DESCRIPTION OF DRAWINGS

FIG. 1 is a block diagram illustrating a digital transmission system which is used to describe an error correction method and device according to a first embodiment of the present invention.

FIG. 2 is a block diagram illustrating details of optical transmission devices 1a and 1b illustrated in FIG. 1.

FIG. 3 is a structural diagram illustrating an OTUk frame as specified in ITU-T Recommendation G.709.

FIG. 4(a) illustrates a configuration of a transmission frame (OTU4V frame format) for an output signal of a soft decision FEC encoder 201 and an input signal of a soft decision FEC decoder 206, and FIG. 4(b) illustrates a configuration of a transmission frame (OTU3V frame format) for the output signal of the soft decision FEC encoder 201 and the input signal of the soft decision decoder 206.

FIG. 5 is a block diagram illustrating details of CMUs 207 and 208 illustrated in FIG. 2.

FIGS. 6(a) and 6(b) relate to a second embodiment in which the same hard decision FEC redundant area as that of the OTUk frame is used as an outer code, illustrating configurations of transmission frames corresponding to FIGS. 4(a) and 4(b), respectively.

FIGS. 7(a) and 7(b) illustrate transmission frames according to a third embodiment, illustrating configurations of transmission frames corresponding to FIGS. 4(a) and 4(b), respectively.

FIGS. 8(a) and 8(b) illustrate transmission frames according to the third embodiment, in which only a soft decision FEC code is used and an FEC redundant area is changed between OTU4V and OTU3V, illustrating configurations of transmission frames corresponding to FIGS. 4(a) and 4(b), respectively.

### DESCRIPTION OF EMBODIMENTS

### First Embodiment

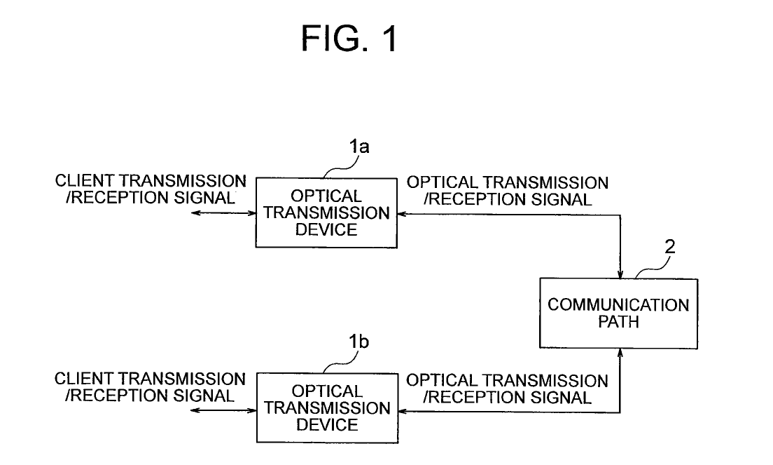

FIG. 1 is a block diagram illustrating a digital transmission system (hereinafter, simply referred to as “transmission system”) which is used to describe an error correction method and device according to a first embodiment of the present invention. Optical transmission devices 1a and 1b of FIG. 1 are used for an optical communication system that transmits a transmission frame formed of information data added with an overhead and an error correction code. The optical transmission devices 1a and 1b perform interconversion between a client transmission/reception signal and an optical transmission/reception signal, for example, mapping/demapping between a client signal and an optical transmission frame, error correction coding/decoding, and electrical/optical conversion, thereby performing intercommunication between the optical transmission devices 1a and 1b via a communication path 2.

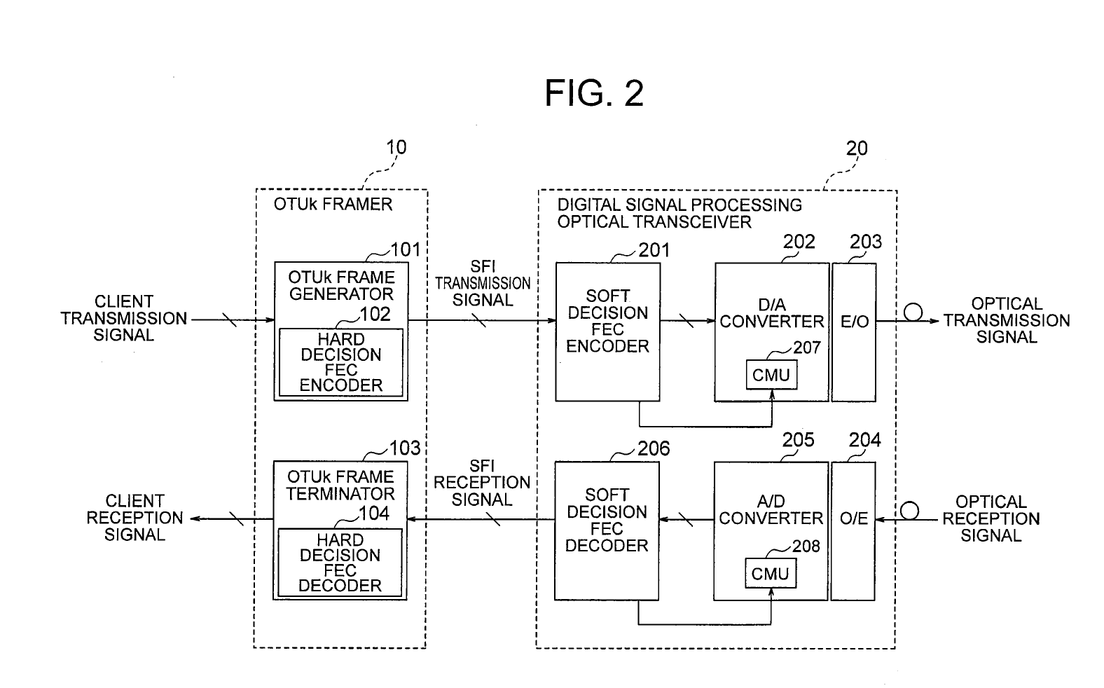

FIG. 2 is a block diagram illustrating details of the optical transmission devices 1a and 1b of FIG. 1. In the optical transmission devices 1a and 1b illustrated in FIG. 2, the size of an FEC redundant area of an FEC frame for storing client signals of different signal types is adjusted in accordance with the client signals so that the relationship (ratio) between the transmission rates of the FEC frame for the respective client signals is adjusted to an approximately N-multiple (N is a positive natural number). In FIG. 2, an optical channel transport unit-k (OTUk) framer 10 includes an OTUk frame generator 101 and an OTUk frame terminator 103. The OTUk frame generator 101 maps a client transmission signal into an OTUk frame and adds information necessary for frame synchronization and maintenance control, to thereby generate an optical transmission frame, and outputs a serdes frame interface (SFI) transmission signal to a digital signal processing optical transceiver 20. The OTUk frame terminator 103 terminates the information necessary for frame synchronization and maintenance control in an SFI reception signal sent from the digital signal processing optical transceiver 20 to thereby demap the client signal from the OTUk frame, and outputs a client reception signal. The OTUk frame generator 101 includes a hard decision FEC encoder 102. The OTUk frame terminator 103 includes a hard decision FEC decoder 104.

The digital signal processing optical transceiver 20 includes a soft decision FEC encoder 201, a digital/analog (D/A) converter 202, an electrical/optical (E/O) 203, an optical/electrical (O/E) 204, an analog/digital (A/D) converter 205, and a soft decision FEC decoder 206. The soft decision FEC encoder 201 encodes the SFI transmission signal sent from the OTUk framer 10 by an error correction code for soft decision. The D/A converter 202 performs D/A conversion on an output signal of the soft decision FEC encoder 201. The E/O 203 converts an analog signal sent from the D/A converter 202 into an optical signal, and outputs an optical transmission signal to the communication path. The O/E 204 converts an optical reception signal sent from the communication path into an analog signal, and outputs the analog signal. The A/D converter 205 converts the analog signal into q-bit soft decision reception data. The soft decision FEC decoder 206 performs soft decision decoding on the soft decision reception data to correct an error, and outputs the SFI reception signal to the OTUk frame 10. The D/A converter 202 includes a CMU 207 for generating a clock corresponding to the transmission rate. The A/D converter 205 includes a CMU 208 for generating a sampling clock corresponding to the transmission rate.

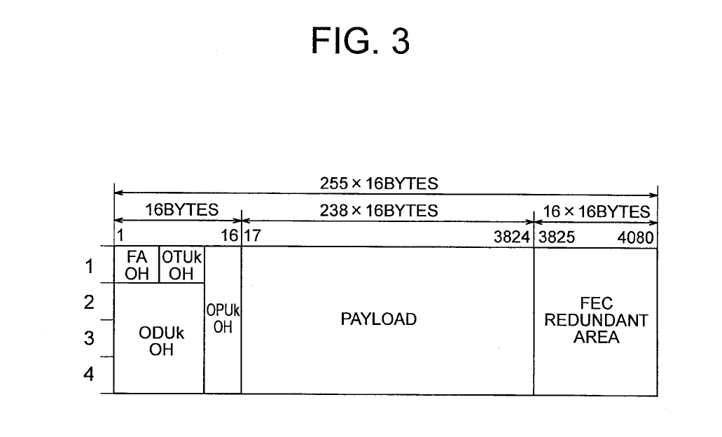

FIG. 3 is a structural diagram illustrating an OTUk frame as specified in ITU-T Recommendation G.709, for example. In FIG. 3, the OTUk frame contains a payload for storing actual communication data such as a client signal, a frame alignment overhead (FA OH) for frame synchronization, an OTUk OH and an optical channel data unit-k overhead (ODUk OH) for maintenance and monitoring information, and an optical channel payload unit-k (OPUk OH) for mapping the payload. The OTUk frame further has an FEC redundant area for storing information on an error correction code for correcting a bit error caused by degradation in optical quality after transmission. A Reed-Solomon code (hereinafter, referred to as RS code) (255,239) is generally used as the error correction code. Note that, a part including the FA OH, the OTUk OH, the ODUk OH, and the OPUk OH is typically called overhead.

In this way, the optical communication system forms a transmission frame by adding the overhead and the error correction code to the payload which is information data to be actually transmitted, and transmits the transmission frame over a long distance at high speed.

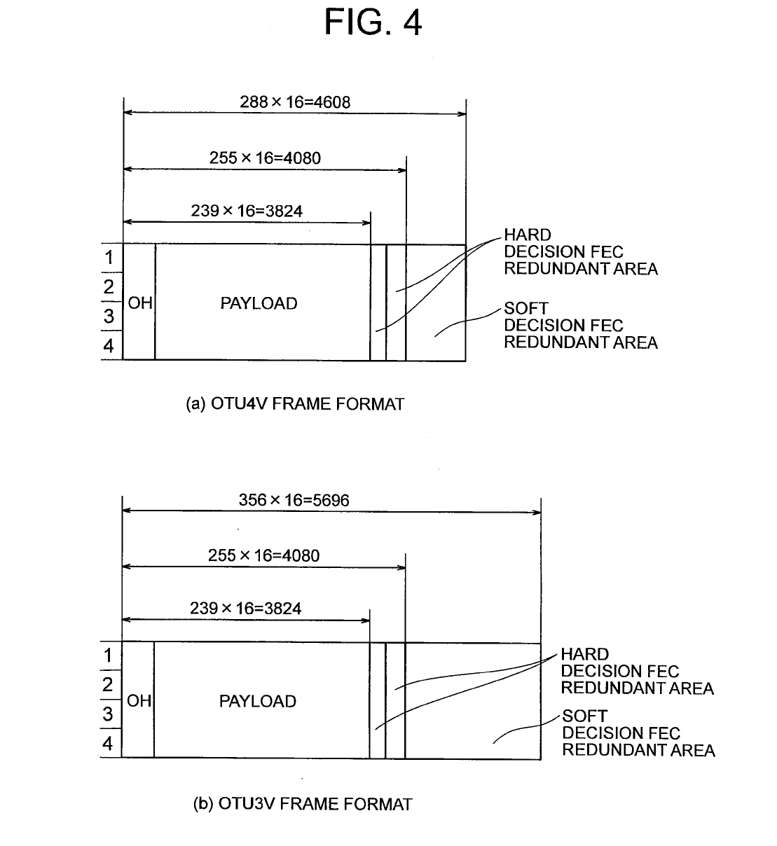

Next, the operation is described with reference to FIG. 4. FIG. 4(a) illustrates the configuration of a transmission frame for the output signal of the soft decision FEC encoder 201 and the input signal of the soft decision FEC decoder 206, and exemplifies an OTU4V frame having an extended OTU4 for storing, as a client signal, a 100 Gigabit Ethernet (trademark) (hereinafter, referred to as 100 GbE) signal under consideration in IEEE802.3ba. The transmission frame of FIG. 4(a) has the same configuration as that of the OTUk frame illustrated in FIG. 3, but the FEC redundant area is divided into two hard decision FEC redundant areas and a soft decision FEC redundant area is added.

Regarding the transmission frame of FIG. 4(a), the OTUk frame generator 101 first maps a client transmission signal to the payload of FIG. 4(a) and adds various pieces of overhead information to the OH, and the hard decision FEC encoder 102 performs error correction coding as an outer code and stores error correction code information in the hard decision FEC redundant areas. At this time, the hard decision FEC encoder 102 performs concatenated coding by a combination of RS codes and BCH codes, for example, and stores the respective pieces of error correction code information in the two divided FEC redundant areas.

Next, the soft decision FEC encoder 201 performs error correction coding for soft decision decoding as an inner code, such as LDPC coding, and stores error correction code information in the soft decision FEC redundant area. The output signal of the OTU4V frame, which is configured by the soft decision FEC encoder 201, is converted into an analog signal by the D/A converter 202, and is further converted by the E/O 203 into an optical signal to be output to the communication path formed of an optical fiber.

On the reception side, on the other hand, the A/D converter 205 performs analog/digital conversion on the received analog signal whose quality has degraded through the communication path, and outputs q-bit soft decision reception data to the soft decision FEC decoder 206. The soft decision FEC decoder 206 performs soft decision decoding processing with the use of the q-bit soft decision information and the error correction code information of the LDPC code stored in the soft decision FEC redundant area, and outputs the resultant signal to the OTUk frame terminator 103 as an SFI reception signal.

In this case, the transmission rate of the OTU4V frame of FIG. 4(a) is about 126 Mb/s. In the case of using multilevel modulation, such as dual-polarization quadrature phase shift keying (DP-QPSK), the transmission rate is 31.5 Gbaud because of four values. The CMU 207 of the D/A converter 202 and the CMU 208 of the A/D converter 205 generate a 63 GHz clock for double oversampling thereof, for example.

FIG. 4(b) similarly illustrates the configuration of a transmission frame for the output signal of the soft decision FEC encoder 201 and the input signal of the soft decision decoder 206, and exemplifies an OTU3V frame having an extended OTU3 for storing, as a client signal, a 40 Gigabit Ethernet (trademark) (hereinafter, referred to as 40 GbE) under consideration in IEEE802.3ba. The transmission frame of FIG. 4(b) has the same configuration as that of the OTUk frame illustrated in FIG. 3, but the FEC redundant area is divided into two hard decision FEC redundant areas and a soft decision FEC redundant area is added.

The soft decision FEC redundant area of FIG. 4(b) is larger than the soft decision FEC redundant area of FIG. 4(a), and the transmission rate is about 63 Gb/s. While the OTU4V frame format illustrated in FIG. 4(a) has 288·16=4,608 columns in total, the OTU4V frame format illustrated in FIG. 4(b) has 356·16=5,696 columns in total. Therefore, for example, in the case of using DP-QPSK modulation, the transmission rate is 15.75 Gbaud, and the CMU 207 of the D/A converter 202 and the CMU 208 of the A/D converter 205 generate a 31.5 GHz clock for double oversampling thereof, for example.

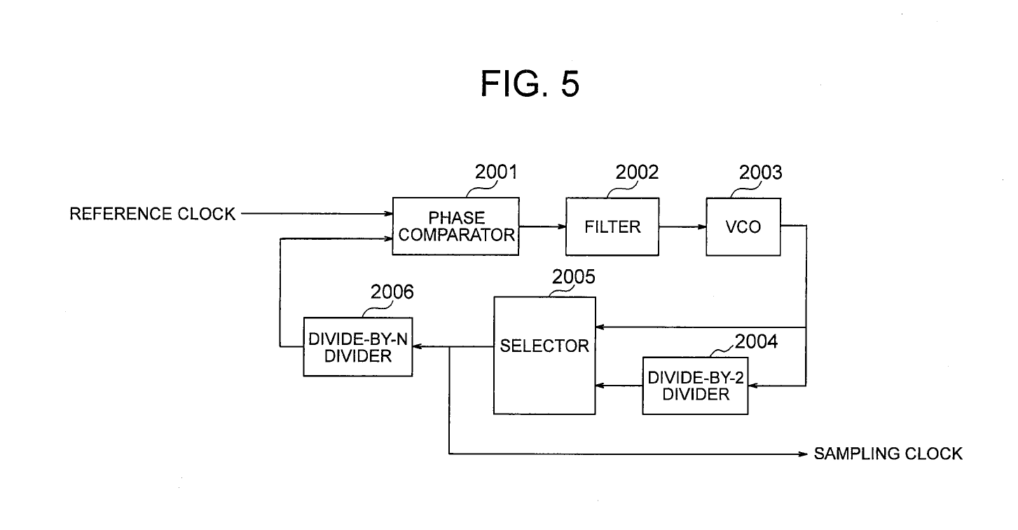

FIG. 5 is a block diagram illustrating details of the CMUs 207 and 208. Each of the CMUs 207 and 208 includes a phase comparator 2001, a filter 2002, a VCO 2003, a divide-by-2 divider 2004, a selector 2005, and a divide-by-N divider 2006. The phase comparator 2001 compares a reference clock sent from the soft decision FEC encoder 201 or the soft decision FEC decoder 206 with a feedback clock sent from the divide-by-N divider 2006. The filter 2002 smooths the comparison result sent from the phase comparator 2001. The VCO 2003 outputs a frequency corresponding to a voltage of the smoothed phase error signal. The divide-by-2 divider 2004 divides the output frequency of the VCO 2003 by 2. The selector 2005 selects one of the clock sent from the VCO 2003 and the clock sent from the divide-by-2 divider 2004, and outputs the selected clock as a sampling clock. The divide-by-N divider 2006 divides the frequency of the sampling clock sent from the selector 2005 by N, and outputs the resultant clock to the phase comparator 2001.

To support OTU4V illustrated in FIG. 4(a), the selector 2005 selects the clock sent from the VCO 2003 and outputs a sampling clock of 63 GHz. To support OTU3V illustrated in FIG. 4(b), on the other hand, the selector 2005 selects the clock sent from the divide-by-2 divider 2004 and outputs a sampling clock of 31.5 GHz.

As described above, through the change of the FEC redundant area in accordance with the client signal to be stored, the transmission rate ratio between OTU4V and OTU3V is adjusted to substantially an integral multiple, and the sampling clock is generated depending on the selection of whether to divide the output frequency of the VCO. Thus, no clock quality degradation such as jitter occurs, which otherwise occurs when the operating frequency range of the VCO is widened greatly, and there is no need to dispose a plurality of VCOs. Thus, the common use of circuits supporting OTU4V and OTU3V becomes possible with a reduced circuit scale.

For example, the soft decision FEC encoder, the soft decision FEC decoder, the D/A converter, and the A/D converter can be formed in a semiconductor integrated circuit so as to be easily shared between OTU4V and OTU3V.

In addition, OTU3V can increase the FEC redundant area, and hence it is possible to improve the coding gain significantly, to thereby increase the transmission distance and increase the capacity owing to multiwavelength.

Note that, the above-mentioned first embodiment has exemplified the soft decision FEC LDPC codes as the inner code, but other soft decision FEC codes, such as convolutional codes and block turbo codes, may be used. Further, the above-mentioned first embodiment has exemplified the concatenated codes of the RS code and the BCH code as the outer code for hard decision FEC, but other concatenated codes, such as concatenated codes of RS and RS and concatenated codes of BCH and BCH, may be used. It should be understood that the use of product codes as the outer code also produces an effect similar to that of the above-mentioned embodiment.

In addition, in the above-mentioned first embodiment, interleaving or deinterleaving may be performed as necessary at the previous stage or the subsequent stage of each error correction coding processing so that an error caused in the transmission path may be dispersed at the time of error correction decoding.

### Second Embodiment

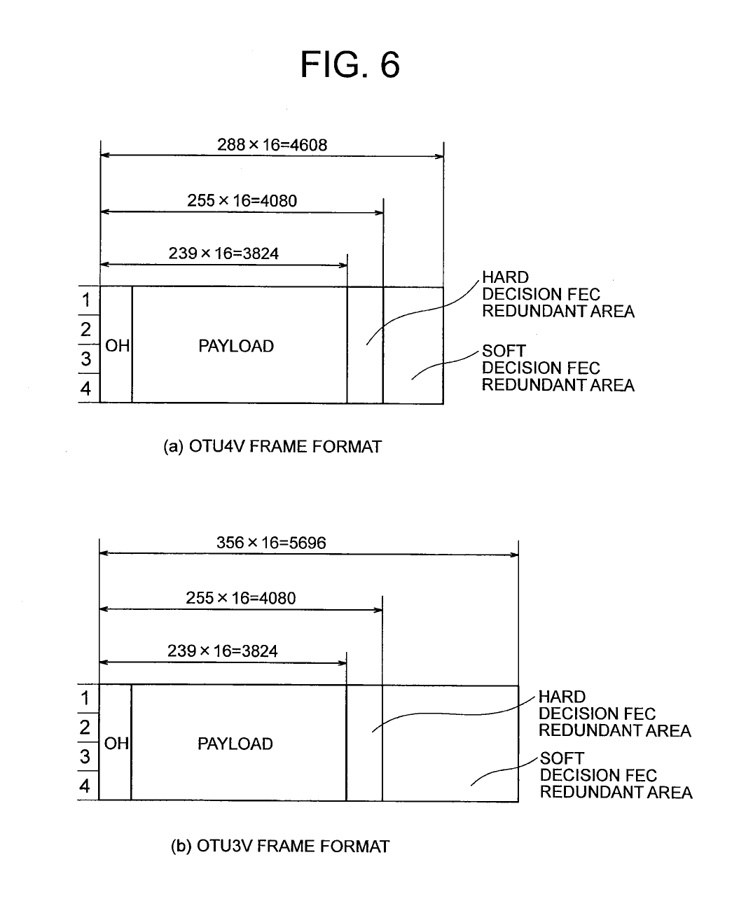

In the first embodiment described above, the hard decision FEC of the outer code uses concatenated codes or product codes. Next, description is given of an embodiment in which the same hard decision FEC redundant area as that of the OTUk frame is used as the outer code as illustrated in FIG. 6. Examples of the hard decision FEC code include commonly-used RS (255,239) codes and parent codes of RS(1020,956) having the increased code length. While the OTU4V frame format illustrated in FIG. 6(a) has 288·16=4,608 columns in total, the OTU3V frame format illustrated in FIG. 6(b) has 356·16=5,696 columns in total.

Note that, the second embodiment has exemplified the RS codes as the outer code, but the outer code may be BCH codes or other codes.

### Third Embodiment

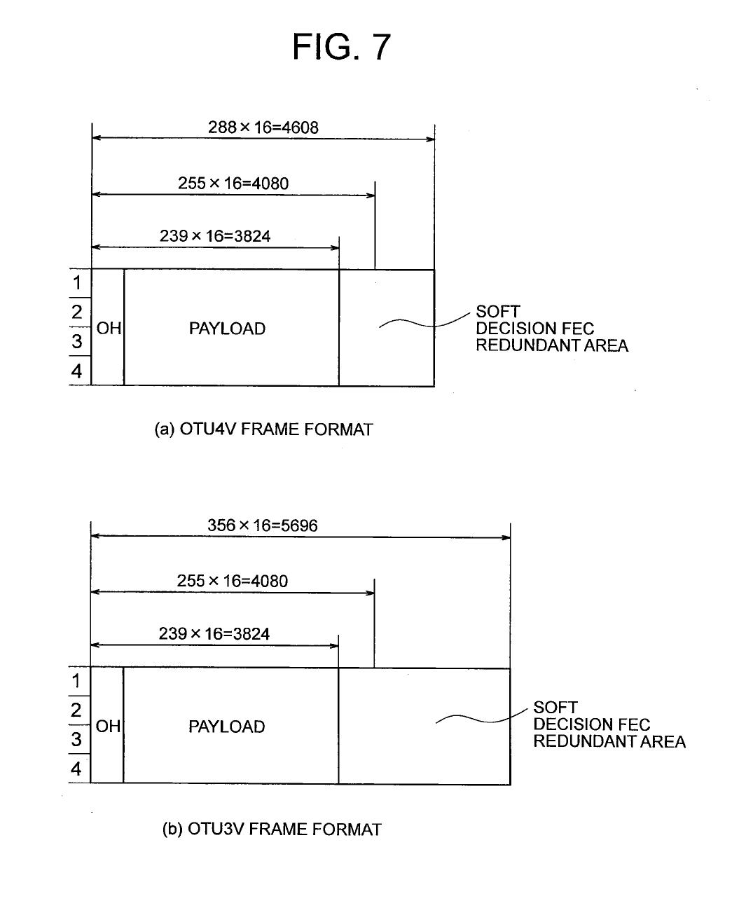

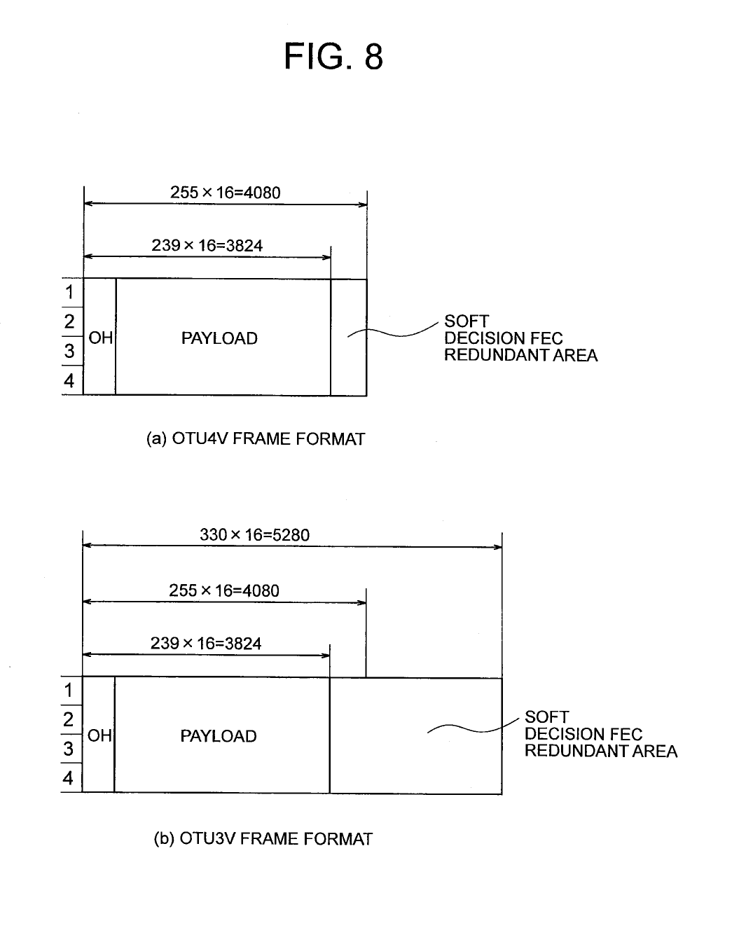

In the second embodiment described above, the hard decision FEC of the outer code uses the RS codes or the like, and the FEC redundant area of the OTUk frame stores coded information on the outer code. Next, description is given of a configuration as illustrated in FIGS. 7 and 8 in which only the soft decision FEC code is used and the FEC redundant area is changed between OTU4V and OTU3V. It should be understood that the use of only the hard decision FEC code also produces a similar effect.

While the OTU4V frame format illustrated in FIG. 7(a) has 288·16=4,608 columns in total, the OTU3V frame format illustrated in FIG. 7(b) has 356·16=5,696 columns. While the OTU4V frame format illustrated in FIG. 8(a) has 255·16=4,080 columns in total, the OTU3V frame format illustrated in FIG. 8(b) has 330·16=5,280 columns.

### Fourth Embodiment

In the embodiments described above, the frame contains the OH, the payload, and the FEC redundant area. It should be understood, however, that the use of a frame added with another area unrelated to error correction, such as a training area, also produces a similar effect.

### REFERENCE SIGNS LIST

1a, 1b optical transmission device, 2 communication path, 10 OTUk framer, 20 digital signal processing optical transceiver, 101 OTUk frame generator, 102 hard decision FEC encoder, 103 OTUk frame terminator, 104 hard decision FEC decoder, 201 soft decision FEC encoder, 202 D/A converter, 203 E/O, 204 O/E, 205 A/D converter, 206 soft decision FEC decoder, 207, 208 CMU, 2001 phase comparator, 2002 filter, 2003 VCO, 2004 divide-by-2 divider, 2005 selector, 2006 divide-by-N divider.

1. An error correction method for an optical communication system that transmits a transmission frame formed of information data added with an overhead and an error correction code,
the error correction method comprising adjusting a size of an FEC redundant area of an FEC frame for storing client signals of different signal types in accordance with the client signals so that a relationship between transmission rates of the FEC frame for the respective client signals is adjusted to an approximately N-multiple (N is a positive natural number).

2. The error correction method according to claim 1, wherein the FEC frame comprises an OTUk frame as specified in ITU-T Recommendation G.709.

3. The error correction method according to claim 1, wherein the FEC frame comprises OTU3V and OTU4V.

4. The error correction method according to claim 3, wherein the OTU4V has 4,608 columns and the OTU3V has 5,696 columns.

5. The error correction method according to claim 3, wherein the OTU4V has 4,080 columns and the OTU3V has 5,280 columns.

6. An error correction device for an optical communication system that transmits a transmission frame formed of information data added with an overhead and an error correction code,
the error correction device comprising:
an optical transmission framer for generating an optical transmission frame based on mapping of a client transmission signal into an optical channel transmission frame and outputting a transmission signal, and for demapping a client signal from the optical channel transmission frame based on an input of a reception signal and outputting a client reception signal;
an FEC encoder for encoding the transmission signal sent from the optical transmission framer by the error correction code;
a D/A converter for performing D/A conversion on an output signal of the FEC encoder and outputting an optical transmission signal to a communication path;
an A/D converter for converting an optical reception signal sent from the communication path into a digital signal; and
an FEC decoder for decoding reception data from an output of the A/D converter to correct an error, and outputting the reception signal to the optical transmission framer,
wherein each of the D/A converter and the A/D converter comprises clock generation means for changing a sampling clock in accordance with client signals of different signal types, and the error correction device adjusts a size of an FEC redundant area of an FEC frame for storing the client signals of different signal types in accordance with the client signals so that a relationship between the transmission rates of the FEC frame for the respective client signals is adjusted to an approximately N-multiple (N is a positive natural number).

7. The error correction device according to claim 6, wherein the clock generation means comprises:
a phase comparator for comparing a reference clock sent from the FEC encoder or the FEC decoder with a feedback clock;
a filter for smoothing a comparison result sent from the phase comparator;
a VCO for outputting a frequency corresponding to a voltage of a smoothed phase error signal;
a divide-by-2 divider for dividing the output frequency of the VCO by 2;
a selector for selecting one of a clock sent from the VCO and a clock sent from the divide-by-2 divider in accordance with the client signal, and outputting the selected clock as a sampling clock; and
a divide-by-N divider for dividing a frequency of the sampling clock sent from the selector by N, and outputting the feedback clock to the phase comparator.
